(19) United States
(12) Patent Application Publication
(10) Pub. No.: US 2026/0123484 A1
(43) Pub. Date: Apr. 30, 2026

(54) POWER MODULE

(71) Applicants: HYUNDAI MOTOR COMPANY, Seoul (KR); KIA CORPORATION, Seoul (KR)

(72) Inventors: Han Jin Do, Hwaseong-si (KR); Jin Myeong Yang, Hwaseong-si (KR); Sung Won Park, Hwaseong-si (KR)

(73) Assignees: HYUNDAI MOTOR COMPANY, Seoul (KR); KIA CORPORATION, Seoul (KR)

(21) Appl. No.: 19/205,463

(22) Filed: May 12, 2025

(30) Foreign Application Priority Data
Oct. 30, 2024 (KR) 10-2024-0150582

(51) Int. Cl. H01L 23/00; H01L 23/498

(52) U.S. Cl. CPC H10W 70/65; H10W 90/401; H10W 72/07553; H10W 72/531; H10W 74/10; H10W 90/756

(57) ABSTRACT

A power module is provided. The power module includes a substrate, a chip mounted on the substrate and having a signal pad, and a lead portion electrically connected to the chip. The lead portion includes a signal lead provided to be spaced apart from the substrate, and a connecting lead connecting the signal lead and the signal pad.

### CROSS-REFERENCE TO RELATED APPLICATION(S)

This application claims the benefit of priority to Korean Patent Application No. 10-2024-0150582 filed on Oct. 30, 2024, in the Korean Intellectual Property Office, the disclosure of which is incorporated herein by reference in its entirety.

### TECHNICAL FIELD

The present disclosure relates to a power module.

### BACKGROUND

Recently, as interest in the environment has increased, eco-friendly vehicles equipped with electric motors as a power source are on the rise. Eco-friendly vehicles are also known as electrified vehicles, and representative examples include electric vehicles (EVs) and hybrid electric vehicles (HEVs). An inverter is used as a component for power control that greatly affects the performance and efficiency of these vehicles.

An inverter is a device that converts direct current (DC) power into alternating current (AC) power, and may drive an electric motor by receiving power from a high-voltage battery. An inverter includes a power module as a core component. The power module processes high voltage and current to perform power conversion.

In some power modules, a wire bonding method is used as a method of connecting signal leads and semiconductor chips. However, in the case of the wire bonding method, it may be difficult to miniaturize the power module because it uses (e.g., requires) securing height for wire bonding. In addition, when connecting the signal lead and the semiconductor chip using the wire bonding method, if the semiconductor chip is disposed inside the substrate, an electrode pattern is used (e.g., required) to form a signal loop, and this electrode pattern may have the problem of complicating the current loop and lowering electrical characteristics of the power module.

Therefore, research for miniaturization and improved electrical characteristics of a power module structure may be useful.

### SUMMARY

An aspect of the present disclosure is to provide a power module useful in miniaturization and having improved electrical characteristics.

According to an aspect of the present disclosure, a power module includes a substrate, a chip mounted on the substrate and having a signal pad, and a lead portion electrically connected to the chip. The lead portion includes a signal lead provided to be spaced apart from the substrate, and a connecting lead connecting the signal lead and the signal pad.

The connecting lead may have one end connected to the signal pad and the other end connected to the signal lead, and an upper surface and a lower surface of at least a portion of the connecting lead, between the one end and the other end, may be provided as flat surfaces.

A portion of the connecting lead overlapping the substrate in a vertical direction may be provided as a flat surface.

The connecting lead may include a first connecting part having one end connected to the signal lead, a second connecting part having one end connected to the signal pad, and a third connecting part connecting the other end of the first connecting part and the other end of the second connecting part. At least portions of an upper surface and a lower surface of the third connecting part may be provided as flat plates.

The substrate may include a lower substrate and an upper substrate disposed on top of the lower substrate, and at least a portion of the third connecting part may be provided between the lower substrate and the upper substrate.

An upper surface and a lower surface of a portion of the third connecting part, provided between the lower substrate and the upper substrate, may be provided as flat plates.

The third connecting part may be provided parallel to at least one of the lower substrate or the upper substrate.

The third connecting part may be bent at least once in a direction parallel to at least one of the lower substrate or the upper substrate.

The first connecting part and the second connecting part may be connected obliquely at both ends of the third connecting part.

The connecting lead may include a first connecting part having one end connected to the signal lead and having an upper surface and a lower surface in a flat shape, and a second connecting part having a bent end bent downwardly at the other end of the first connecting part, the bent end being connected to the signal pad.

The power module may further include a molded portion provided to surround the substrate and the chip. The signal lead may have one end spaced apart from the substrate inside the molded portion and the other end exposed to an outside of the molded portion, and the connecting lead may connect one end of the signal lead to the signal pad.

The substrate may include a lower substrate at least partially exposed to a lower surface of the molded portion, and an upper substrate disposed above the lower substrate and at least partially exposed to an upper surface of the molded portion.

According to an aspect of the present disclosure, a power module includes a substrate including a lower substrate and an upper substrate disposed above the lower substrate, a chip mounted on the substrate and having a signal pad, a molded portion provided to surround the substrate and the chip, and a lead portion having one end electrically connected to the signal pad inside of the molded portion and the other end exposed to an outside of the molded portion. A portion of the lead portion disposed between the lower substrate and the upper substrate has an upper surface and a lower surface in a flat shape.

The lead portion may include a signal lead for transmitting a control signal. The signal lead may include a first part having one end connected to the signal pad inside the molded portion, and a second part having one end connected to the other end of the first part and the other end exposed to an outside of the molded portion. A widthwise length of the first part may be provided shorter than a widthwise length of the second part.

The first part may be provided by being bent at least once in a direction parallel to the substrate.

### BRIEF DESCRIPTION OF DRAWINGS

The above and other aspects and features of the present disclosure may be more understood from the following detailed description, taken in conjunction with the accompanying drawings, in which

FIG. 1 is a perspective view of a power module according to an embodiment.

FIG. 2 is a perspective view illustrating a state in which a molded portion is removed from the power module illustrated in FIG. 1.

FIG. 3 is a cross-sectional view taken along line I-I′ of FIG. 1.

FIG. 4A is a perspective view illustrating a state in which a molded portion is removed from a power module according to another embodiment, and FIG. 4B is a cross-sectional view of a power module according to another embodiment.

FIG. 5A is a perspective view illustrating a state in which a molded portion is removed from a power module according to another embodiment, and FIG. 5B is a cross-sectional view of a power module according to another embodiment.

FIG. 6A is a perspective view illustrating a state in which a molded portion is removed from a power module according to another embodiment, and FIG. 6B is a cross-sectional view of a power module according to another embodiment.

### DETAILED DESCRIPTION

The present disclosure may have various modifications and various embodiments, and specific embodiments are illustrated in the drawings and described in detail. However, this is not intended to limit the present disclosure to specific embodiments, and it should be understood that modifications, equivalents, and substitutes included in the spirit and technical scope of the present disclosure are included.

The terms first, second, and the like may be used to describe various components, but the components may not be limited by the terms. The terms are used for the purpose of distinguishing one component from another. For example, without departing from the scope of the present disclosure, the first component may be referred to as the second component, and similarly, the second component may also be referred to as the first component. The term ‘and/or’ includes a combination of a plurality of related described items or any of a plurality of related described items.

The terms “unit,” “part,” “portion,” and the like may be used to describe various components, but the components may not be limited by the terms. The above terms may refer to not physically/visibly distinct configurations, but also to functions or configurations of corresponding parts even if the distinction/division is not defined. The terms used in this application are used to describe specific embodiments and are not intended to limit the present disclosure. The singular expression includes plural expressions unless the context indicates otherwise. In this application, the terms “include,” “have,” and the like may be understood to indicate the presence of features, numbers, steps, operations, components, parts, or combinations thereof described in the specification, but do not preclude the possibility of the presence or addition of one or more other features, numbers, steps, operations, components, parts, or combinations thereof.

Unless otherwise defined, terms used herein, including technical or scientific terms, have the same meaning as that generally understood by a person of ordinary skill in the art to which the present disclosure belongs. Terms that are defined in commonly used dictionaries may be interpreted as having a meaning consistent with the meaning they have in the context of the relevant technology, and are not interpreted in an ideal or overly formal sense unless explicitly defined in this application.

In the description below, the terms “front,” “rear,” “upper,” “lower,” and the like used in relation to direction may be explained based on the illustration in the drawing.

Hereinafter, with reference to the attached drawings, an example embodiment is described in more detail.

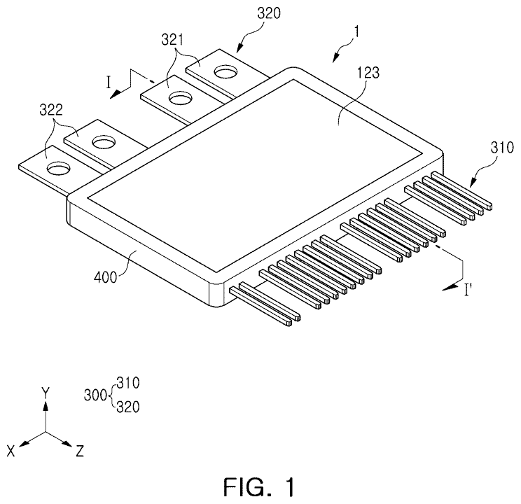

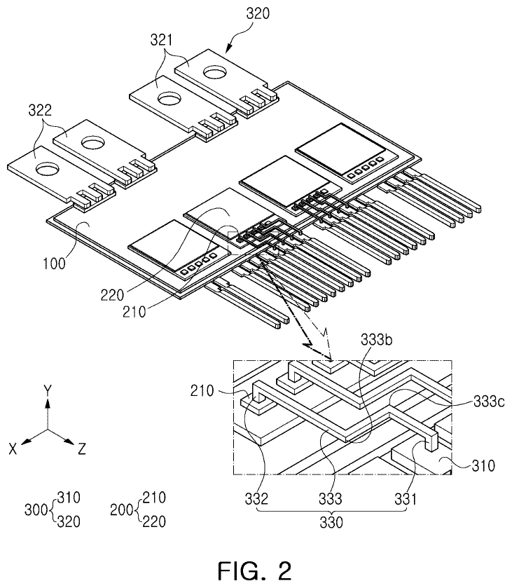

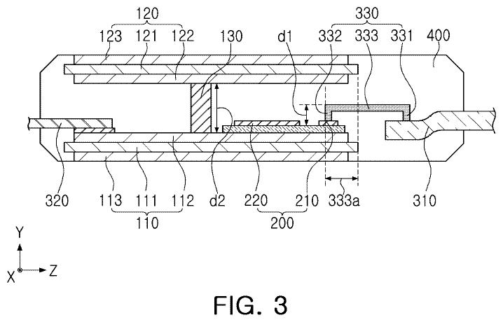

FIG. 1 is a perspective view of a power module according to an embodiment, FIG. 2 is a perspective view illustrating the power module illustrated in FIG. 1 with the molded portion removed, and FIG. 3 is a cross-sectional view taken along line I-I′ of FIG. 1.

Referring to FIGS. 1 to 3, a power module 1 according to an embodiment may include a substrate 100, a chip 200, and a lead portion 300.

The substrate 100 may include a lower substrate 110 and an upper substrate 120. The lower substrate 110 may include a first insulating layer 111, a first internal metal layer 112 provided on an upper surface of the first insulating layer 111, and a first external metal layer 113 provided on a lower surface of the first insulating layer 111. The upper substrate 120 may include a second insulating layer 121, a second internal metal layer 122 provided on the lower surface of the second insulating layer 121, and a second external metal layer 123 provided on the upper surface of the second insulating substrate 122.

A circuit pattern forming an electrical connection relationship between the inside and the outside of the power module 1 may be formed on the first internal metal layer 112 and the second internal metal layer 122.

At least portions of the first external metal layer 113 and the second external metal layer 123 may be exposed to the outside of the molded portion 400. A separate cooling channel (not illustrated) may be connected to the portions of the first external metal layer 113 and the second external metal layer 123 exposed to the outside of the molded portion 200. The first external metal layer 113 and the second external metal layer 123 may release heat generated during operation of the power module 1 to the outside.

The upper substrate 120 may be disposed above the lower substrate 110. A spacer 130 may be provided between the upper substrate 120 and the lower substrate 110, for electrical/physical connection between the upper substrate 120 and the lower substrate 110. The spacer 130 may separate the upper substrate 120 and the lower substrate 110 and (e.g., substantially) simultaneously, electrically connect the upper substrate 120 and the lower substrate 110.

The chip 200 may be mounted on the substrate 100. For example, the chip 200 may be mounted on the upper portion of the lower substrate 110 or the lower portion of the upper substrate 120. The chip 200 may be disposed between the lower substrate 110 and the upper substrate 120.

The chip 200 may be electrically connected to at least one of the first internal metal layer 112 or the second internal metal layer 122.

The chip 200 may include at least one of, for example, an insulated gate bipolar transistor (IGBT), a compound semiconductor (SIC), a shunt circuit, a silicon controlled rectifier (SCR), a power transistor, a MOS transistor, a power rectifier, a power regulator, or a diode.

The chip 200 may be electrically connected to the lead portion 300. The chip 200 may include a signal pad 210 connected to a signal lead 310 of the lead portion 300 and a power pad 220 connected to a power lead 320 of the lead portion 300. The signal pad 210 may receive a control signal from the signal lead 310 or transmit status information of the chip 200. The power pad 220 may receive power from the power lead 320 and output the received power. For example, the chip 200 may receive a high voltage direct current through the power pad 220, convert the direct current into an alternating current, and output the converted current. The power pad 220 of the chip 200 may be directly connected to the power lead 320 or may be connected thereto via a circuit pattern formed on the substrate 100. A signal pad 210 and a power pad 220 may be provided in multiple units in one chip 200. The size of the signal pad 210 may be provided relatively smaller than the size of the power pad 220. The signal pad 210 may be directly connected to the signal lead 310 or may be connected thereto via a connecting lead 330. In addition, the signal pad 210 may be connected to the signal lead 310 via the first internal metal layer 112 or the second internal metal layer 122 of the substrate 100.

The lead portion 300 may be provided to input/output current or input/output a control signal. One end of the lead portion 300 may be electrically connected to the chip 200 in the inside of the molded portion 400. The other end of the lead portion 300 may be exposed to the outside of the molded portion 400.

The lead portion 300 may include a plurality of leads, and the leads may include a signal lead 310 for transmitting a control signal, a power lead 320 for transmitting power, and a connecting lead 330 for connecting the signal lead 310 and the chip 200.

The signal lead 310 may be provided to input a control signal to the chip 200 mounted on the substrate 100 or to receive status information of the chip 200. One end of the signal lead 310 may be disposed inside the molded portion 400 and the other end thereof may be exposed to the outside of the molded portion 400.

A plurality of the signal leads 310 may be disposed adjacent to each other in one direction on one surface of the molded portion 400. For example, the signal leads 310 may be disposed adjacent to each other in the X-axis direction shown on FIG. 1.

The signal lead 310 may be provided so that one end thereof is spaced apart from the substrate 100 inside the molded portion 400. For example, the inner end of the signal lead 310 may not be disposed between the lower substrate 110 and the upper substrate 120, but may be disposed to be spaced apart from the substrate 100.

The connecting lead 330 may connect the signal lead 310 to the signal pad 210 of the chip 200. The connecting lead 330 may connect the signal lead 310 and the signal pad 210 inside the molded portion 400. The connecting lead 330 may be provided with a conductive material. A height d1 of the connecting lead 330 may be provided lower (e.g., less) than a height d2 between the lower substrate 110 and the upper substrate 120.

The connecting lead 330 may have one end connected to the signal pad 210 and the other end connected to the signal lead 310. Accordingly, one end of the connecting lead 330 may be provided between the lower substrate 110 and the upper substrate 120, and the other end may be provided on the outside of the lower substrate 110 and the upper substrate 120. At least a portion between the one end and the other end of the connecting lead 330 may be provided with the upper and lower surfaces as flat plates. For example, upper and lower surfaces of a portion 333a of the connecting lead 330, vertically overlapping the substrate 100, may be provided as flat plates. By providing the upper and lower surfaces of the portion 333a of the connecting lead 330, which overlaps the substrate 100, in a flat shape, the height d2 between the lower substrate 110 and the upper substrate 120 may be reduced compared to connecting the connecting lead and the signal pad using a wire bonding method. Therefore, there may be a useful effect in miniaturizing the power module 1.

The connecting lead 330 may include, for example, a first connecting part 331 having one end connected to the signal lead 310, a second connecting part 332 having one end connected to the signal pad 210, and a third connecting part 333 connecting the other end of the first connecting part 331 and the other end of the second connecting part 332. The first connecting part 331, the second connecting part 332, and the third connecting part 333 may be provided as one piece. For example, the first connecting part 331 and the second connecting part 332 may be formed by bending both ends of the third connecting part 333 downward.

At least a portion of the upper surface and at least a portion of the lower surface of the third connecting part 333 may be provided as flat plates. For example, at least a portion of the third connecting part 333 may be provided between the lower substrate 110 and the upper substrate 120, and the upper surface and the lower surface of the portion 333a of the third connecting part 333 (e.g., provided between the lower substrate 110 and the upper substrate 120) may be provided as flat plates. Also, the third connecting part 333 may be provided parallel to at least one of the lower substrate 110 or the upper substrate 120. As shown (e.g., at this time), the third connecting part 333 may be provided by being bent at least once in a direction parallel to at least one of the lower substrate 110 or the upper substrate 120. When the third connecting part 333 is provided by being bent, the third connecting part 333 may be provided with at least one or more corner parts 333b and 333c. The shape and number of times the third connecting part 333 is bent may be changed depending on the position of where the chip 200 is disposed on the substrate 100.

By providing the portion of the third connecting part 333 provided between the lower substrate 110 and the upper substrate 120 in a flat shape, a height d2 between the lower substrate 110 and the upper substrate 120 may be reduced compared to a wire bonding method, and thus, there is a useful effect in miniaturizing the power module 1.

The power lead 320 may be provided to supply power to the chip 200 mounted on the substrate 100 or to output power converted by the chip 200. The power lead 320 may include, for example, a plurality of input terminals 321 that are connected to a high-voltage battery (not illustrated) to supply direct current to the chip 200 and a plurality of output terminals 322 that output alternating current converted by the chip 200.

One end of the input terminal 321 and one end of the output terminal 322 may be disposed inside the molded portion 400 and electrically connected to the substrate 100 or the chip 200. The other ends of the input terminal 321 and the output terminal 322 may be exposed to the outside of the molded portion 200. The input terminal 321 and the output terminal 322 may be disposed adjacent to each other in one direction. For example, a plurality of input terminals 321 and output terminals 322 may be disposed adjacent to each other in the X-axis direction on the other surface of the molded portion 200.

The molded portion 400 may form the exterior of the power module 1. The molded portion 400 may be provided to surround the substrate 100 and the chip 200. The molded portion 400 may be provided with (e.g., various) engineering plastics. For example, the molded portion 400 may be provided using an epoxy molding compound (EMC).

The molded portion 400 may be provided to surround the inner space between the lower substrate 110 and the upper substrate 120 and the outer peripheral surfaces of the lower substrate 110 and the upper substrate 120. At least portions of the first external metal layer 113 of the lower substrate 110 and the second external metal layer 123 of the upper substrate 120 may be exposed to the outside of the molded portion 400. For example, at least a portion of the first external metal layer 113 may be exposed to the lower surface of the molded portion 400, and at least a portion of the second external metal layer 123 may be exposed to the upper surface of the molded portion 400.

The signal lead 310 may be exposed to the outside on one surface of the molded portion 400, and the power lead 320 may be exposed to the outside on the other surface of the molded portion 400. However, the positions at which the signal lead 310 and the power lead 320 are exposed are not limited to the above-described embodiment, and may be exposed to the outside in various positions of the molded portion 400 depending on design needs.

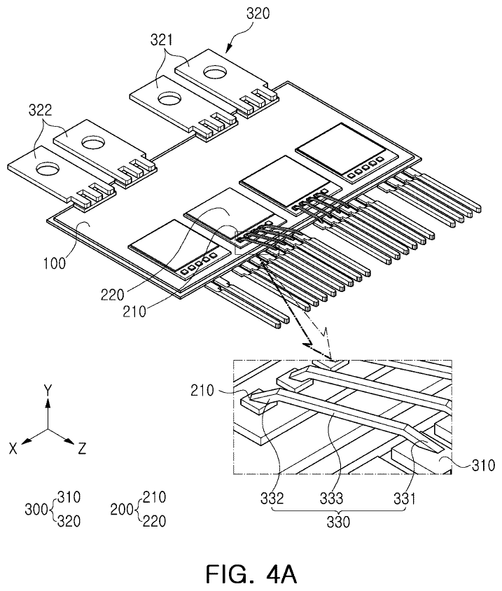

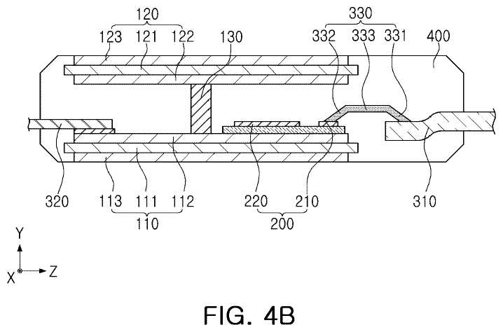

FIG. 4A is a perspective view illustrating a power module according to another embodiment with the molded portion removed, and FIG. 4B is a cross-sectional view of a power module according to another embodiment. A power module 1 according to another embodiment illustrated in FIG. 4A and/or FIG. 4B is substantially the same or similar (e.g., identical) to the power module 1 illustrated in FIGS. 1 to 3 except for the configuration of a connecting lead 330. Therefore, a detailed description of the same configuration is omitted and may be substituted with the description described above.

Referring to FIG. 4A or FIG. 4B, the power module 1 according to another embodiment may include a substrate 100, a chip 200, and a lead portion 300.

The lead portion 300 may be provided to input and output current or input and output a control signal. The lead portion 300 may include a plurality of leads, and the leads may include a signal lead 310 for transmitting a control signal, a power lead 320 for transmitting power, and a connecting lead 330 for connecting the signal lead 310 and the chip 200.

The signal lead 310 may be provided so that one end is spaced apart from the substrate 100 inside the molded portion 400. For example, the inner end of the signal lead 310 may not be disposed between the lower substrate 110 and the upper substrate 120, but may be spaced apart from the substrate 100.

The connecting lead 330 may connect the signal lead 310 and the signal pad 210 of the chip 200. One end of the connecting lead 330 may be connected to the signal pad 210 and the other end may be connected to the signal lead 310. One end of the connecting lead 330 may be provided between the lower substrate 110 and the upper substrate 120, and the other end may be provided on the outside of the lower substrate 110 and the upper substrate 120.

The connecting lead 330 may include, for example, a first connecting part 331 having one end connected to the signal lead 310, a second connecting part 332 having one end connected to the signal pad 210, and a third connecting part 333 connecting the other end of the first connecting part 331 and the other end of the second connecting part 332. The first connecting part 331, the second connecting part 332, and the third connecting part 333 may be provided as one piece. For example, the first connecting part 331 and the second connecting part 332 may be formed by bending both ends of the third connecting part 333. The first connecting part 331 and the second connecting part 332 may be provided to be inclined at both ends of the third connecting part 333. For example, the first connecting part 331 may be provided to be inclined upwardly at the end of the signal lead 310 toward the third connecting part 333, and the second connecting part 332 may be provided to be inclined upward from the signal pad 210 toward the third connecting part 333. By providing the first connecting part 331 and the second connecting part 332 obliquely, the length of the connecting lead 330 connecting the signal pad 210 and the signal lead 310 may be significantly reduced. Accordingly, the signal path transmitted through the signal lead 310 is shortened, so that the electrical characteristics of the power module 1 may be improved.

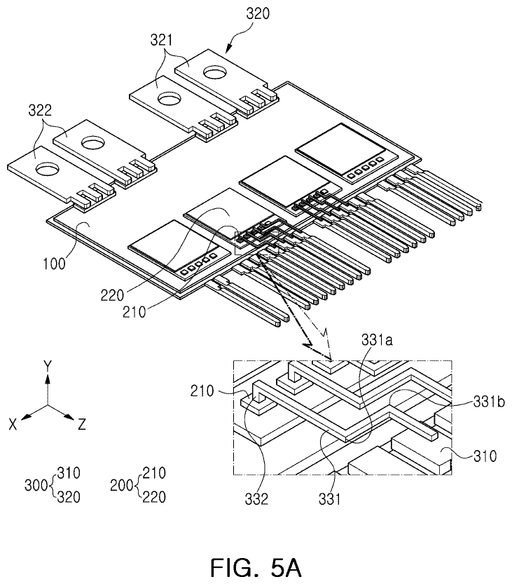

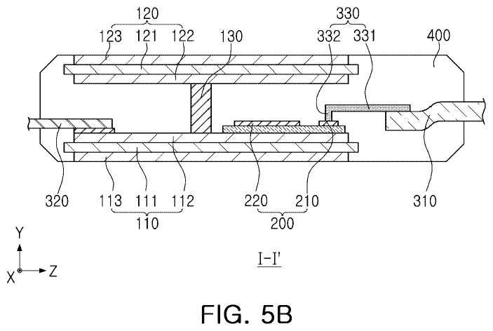

FIG. 5A is a perspective view illustrating a power module according to another embodiment with the molded portion removed, and FIG. 5B is a cross-sectional view of a power module according to another embodiment. The power module 1 according to another embodiment illustrated in FIG. 5A or FIG. 5B is substantially the same or similar (e.g., identical) to the power module 1 illustrated in FIGS. 1 to 3 except for the configuration of the connecting lead 330. Therefore, a detailed description of the same configuration may be omitted as the description is provided herein above.

Referring to FIG. 5A or FIG. 5B, the power module 1 according to another embodiment may include a substrate 100, a chip 200, and a lead portion 300.

The lead portion 300 may include a plurality of leads, and the leads may include a signal lead 310 for transmitting a control signal, a power lead 320 for transmitting power, and a connecting lead 330 for connecting the signal lead 310 and the chip 200.

The signal lead 310 may be provided so that one end is spaced apart from the substrate 100 inside the molded portion 400. For example, the inner end of the signal lead 310 may not be disposed between the lower substrate 110 and the upper substrate 120, but may be disposed spaced apart from the substrate 100.

The connecting lead 330 may connect the signal lead 310 and the signal pad 210 of the chip 200. The connecting lead 330 may have one end connected to the signal pad 210 and the other end connected to the signal lead 310. One end of the connecting lead 330 may be provided between the lower substrate 110 and the upper substrate 120, and the other end may be provided on the outside of the lower substrate 110 and the upper substrate 120.

The connecting lead 330 may include, for example, a first connecting part 331 having one end connected to the signal lead 310 and a second connecting part 332 having one end connected to the signal pad 210. The first connecting part 331 and the second connecting part 332 may be provided as one piece. For example, the second connecting part 332 may be provided by being bent downward from one end of the first connecting part 331. Accordingly, the side shape of the connecting lead 330 may be provided in an overall “¬” shape. The first connecting part 331 may be provided parallel to at least one of the lower substrate 110 or the upper substrate 120. At this time, the first connecting part 331 may be provided at least once in a direction parallel to at least one of the lower substrate 110 or the upper substrate 120. In the case in which the first connecting part 331 is provided by being bent, the first connecting part 331 may be provided with at least one or more corner parts 331a and 331b. The shape and number of times the first connecting part 331 is bent may be changed depending on the position where the chip 200 is disposed on the substrate 100.

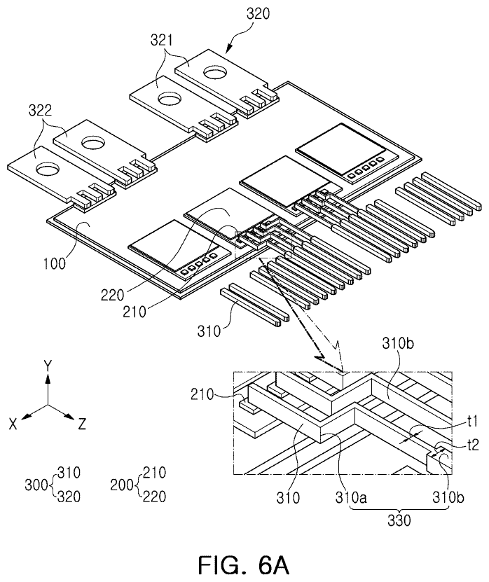

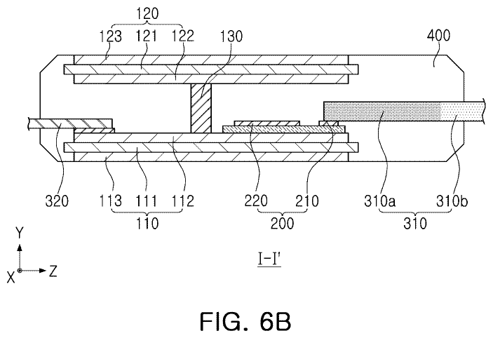

FIG. 6A is a perspective view illustrating a power module according to another embodiment with the molded portion removed, and FIG. 6B is a cross-sectional view of a power module according to another embodiment. The configurations of the substrate 100, the chip 200, and the molded portion 400 of the power module 1 according to another embodiment is the same as the power module illustrated in FIGS. 1 to 3. Therefore, the description of the same configuration is omitted and substituted with the description described above.

Referring to FIG. 6A or FIG. 6B, a power module 1 according to another embodiment may include a substrate 100, a chip 200, and a lead portion 300.

The lead portion 300 may include a plurality of leads, and the leads may include a signal lead 310 for transmitting a control signal and a power lead 320 for transmitting power.

The signal lead 310 may be provided to input a control signal to a chip 200 mounted on a substrate 100 or to receive status information of the chip 200. The signal lead 310 may have one end positioned inside the molded portion 400 and the other end exposed to the outside of the molded portion 400. For example, the signal lead 310 may include a first part 310a whose one end is connected to the signal pad 210 inside the molded portion 400 and a second part 320b whose one end is connected to the other end of the first part 310a and the other end is exposed to the outside of the molded portion 400. The first part 310a may be bent at least once in a direction parallel to the substrate 100. The shape and number of times the first part 310a is bent may be changed in accordance with the position of the chip 200 mounted on the substrate 100.

The first part 310a and the second part 310b may provide (e.g., mean) regions discriminated by the width-direction length. In detail, the first part 310a and the second part 310b may refer to regions distinguished by the width-direction length in a single member. In this case, the width-direction may refer to the direction in which a plurality of signal pads 210 are disposed, and may refer to the X-axis direction based on FIG. 6A. A width-direction length t1 of the first part 310a may be provided to be shorter than the width-direction length of the second part 320b. Since the signal pads 210 of the chip 200 are spaced closely together, the width-direction length t1 of the first part 310a of the signal lead 310 is provided relatively short, thereby securing an insulation distance between the signal leads 310 and preventing interference during coupling.

As set forth herein above, a power module according to an embodiment is provided in miniaturization and has an effect of improving electrical characteristics.

While example embodiments have been illustrated and described above, it may be apparent to those skilled in the art that modifications and variations could be made without departing from the scope of the present disclosure as provided by the claims.

What is claimed is:

1. A power module comprising:
a substrate;
a chip mounted on the substrate and having a signal pad; and
a lead portion electrically connected to the chip,
wherein the lead portion includes,
a signal lead provided to be spaced apart from the substrate, and
a connecting lead connecting the signal lead and the signal pad.

2. The power module of claim 1, wherein the connecting lead has a first end connected to the signal pad and a second end connected to the signal lead, and wherein the connecting lead has an upper surface and a lower surface, and wherein at least a portion of the upper surface of the connecting lead between the first end and the second end is provided as a flat surface, and wherein at least a portion of the lower surface of the connecting lead between the first end and the second end is provided as a flat surface.

3. The power module of claim 2, wherein a portion of the connecting lead overlaps the substrate in a vertical direction.

4. The power module of claim 3, wherein the portion of the connecting lead overlapping the substrate is provided as a flat surface.

5. The power module of claim 1, wherein the connecting lead includes,
a first connecting part having a first end connected to the signal lead;
a second connecting part having a first end connected to the signal pad; and
a third connecting part connecting a second end of the first connecting part and a second end of the second connecting part.

6. The power module of claim 5, wherein the third connecting part has an upper surface and a lower surface, and wherein at least a portion of the upper surface of the third connecting part is provided as a flat plate.

7. The power module of claim 6, wherein at least a portion of the lower surface of the third connecting part is provided as a flat plate.

8. The power module of claim 5, wherein the substrate includes a lower substrate and an upper substrate disposed on top of the lower substrate.

9. The power module of claim 8, wherein at least a portion of the third connecting part is provided between the lower substrate and the upper substrate.

10. The power module of claim 9, wherein an upper surface of the portion of the third connecting part provided between the lower substrate and the upper substrate is provided as a flat plate, and wherein a lower surface of the portion of the third connecting part provided between the lower substrate and the upper substrate is provided as a flat plate.

11. The power module of claim 5, wherein the substrate includes a lower substrate and an upper substrate, and wherein the third connecting part is provided parallel to at least one of the lower substrate or the upper substrate.

12. The power module of claim 11, wherein the third connecting part is bent at least once in a direction parallel to at least one of the lower substrate or the upper substrate.

13. The power module of claim 5, wherein the first connecting part and the second connecting part are connected obliquely at both ends of the third connecting part.

14. The power module of claim 1, wherein the connecting lead includes,
a first connecting part having a first end connected to the signal lead and having an upper surface and a lower surface in a flat shape; and
a second connecting part having a bent end bent downwardly at a second end of the first connecting part, the bent end being connected to the signal pad.

15. The power module of claim 1, further comprising a molded portion provided to surround the substrate and the chip,
wherein the signal lead has a first end spaced apart from the substrate inside the molded portion and a second end exposed to an outside of the molded portion, and
the connecting lead connects at least one of the first end or the second end of the signal lead to the signal pad.

16. The power module of claim 15, wherein the substrate includes,
a lower substrate at least partially exposed to a lower surface of the molded portion; and
an upper substrate disposed above the lower substrate and at least partially exposed to an upper surface of the molded portion.

17. A power module comprising:
a substrate including a lower substrate and an upper substrate disposed above the lower substrate;
a chip mounted on the substrate and having a signal pad;
a molded portion provided to surround the substrate and the chip; and
a lead portion having a first end electrically connected to the signal pad inside of the molded portion and a second end exposed to an outside of the molded portion,
wherein a portion of the lead portion disposed between the lower substrate and the upper substrate has an upper surface and a lower surface in a flat shape.

18. The power module of claim 17, wherein the lead portion includes a signal lead for transmitting a control signal.

19. The power module of claim 18,
wherein the signal lead includes
a first part having a first end connected to the signal pad inside the molded portion; and
a second part having a first end connected to a second end of the first part and the second end exposed to an outside of the molded portion, wherein a widthwise length of the first part is provided shorter than a widthwise length of the second part.

20. The power module of claim 19, wherein the first part is provided by being bent at least once in a direction parallel to the substrate.
